(19) United States
(12) Patent Application Publication
(10) Pub. No.: US 2024/0297176 A1
(43) Pub. Date: Sep. 5, 2024

(54) ARRAY BASEPLATE AND PREPARATION METHOD THEREOF, AND DISPLAY DEVICE

(71) Applicant: BOE TECHNOLOGY GROUP CO., LTD., Beijing (CN)

(72) Inventors: Can Zhang, Beijing (CN); Xinxin Zhao, Beijing (CN); Ning Cong, Beijing (CN); Minghua Xuan, Beijing (CN); Xiaochuan Chen, Beijing (CN)

(73) Assignee: BOE TECHNOLOGY GROUP CO., LTD., Beijing (CN)

(21) Appl. No.: 18/026,465

(22) PCT Filed: Jun. 15, 2022
(86) PCT No.: PCT/CN2022/098989

§ 371 Date: Mar. 15, 2023

(51) Int. Cl. H01L 27/12; H01L 25/075; H01L 25/16; H01L 33/38; H01L 33/62

(52) U.S. Cl. CPC H01L 27/124; H01L 25/0753; H01L 25/167; H01L 33/382; H01L 33/62; H01L 2933/0066

(57) ABSTRACT

An array baseplate and a preparation method thereof, and a display device. The array baseplate includes: a substrate; a drive unit disposed on one side of the substrate; and a light-emitting unit including at least one light-emitting subunit and disposed on a side of the substrate away from the drive unit, wherein the light-emitting unit is electrically connected to the drive unit through a wiring penetrating the substrate, and at least part area of each light-emitting subunit is in direct contact with the substrate. The light-emitting unit and the drive unit in the array baseplate are located on two sides of the substrate, and at least part area of the light-emitting subunit is in direct contact with the substrate.

### TECHNICAL FIELD

The present application relates to the technical field of displaying and more particularly, to an array baseplate and a preparation method thereof, and a display device.

### BACKGROUND

With the rapid development of display technology, silicon-based light-emitting diode (LED) micro-display products have become a new research focus due to their characteristics of self-illumination, lightweight, fast response, high temperature resistance, high brightness and long life.

At present, the silicon-based light-emitting diode micro-display products are prepared by bonding a drive backplane and a silicon-based light-emitting diode chip, and then removing a silicon-based substrate of the light-emitting diode chip. However, in the process of removing the silicon-based substrate of the light-emitting diode chip, the drive circuit in the drive backplane is easily damaged, thus reducing the yield of the display product and reducing the display effect.

### SUMMARY

The embodiments of the present application employ the following technical solutions:
in the first aspect, the embodiment of the present application provides an array baseplate, including:
a substrate;
a drive unit disposed on one side of the substrate; and
a light-emitting unit including at least one light-emitting subunit and disposed on a side of the substrate away from the drive unit, wherein the light-emitting unit is electrically connected to the drive unit through a wiring penetrating the substrate, and at least part area of each light-emitting subunit is in direct contact with the substrate.

In some embodiments of the present application, the array baseplate includes a first wiring and a second wiring, the light-emitting subunit includes an epitaxial layer; the first wiring and the second wiring are electrically connected to the epitaxial layer, and the first wiring and the second wiring are electrically connected to the drive unit;
wherein, at least part area of the epitaxial layer is in direct contact with the substrate.

In some embodiments of the present application, the epitaxial layer includes a transition sublayer, a first sublayer, a second sublayer and a third sublayer that are arranged on the substrate in sequence;
wherein, at least part area of the transition sublayer is in direct contact with the substrate.

In some embodiments of the present application, at least part area of at least one wiring of the first wiring and the second wiring passes through the substrate and extends to the side of the substrate disposing the drive unit, and is electrically connected to the drive unit.

In some embodiments of the present application, the light-emitting unit includes one light-emitting subunit, the substrate is provided with a first through hole and a second through hole, at least part area of the first wiring is located in the first through hole, and at least part area of the second wiring is located in the second through hole.

In some embodiments of the present application, the first wiring is located in the first through hole, a part area of the second wiring is located on a side of the epitaxial layer away from the substrate, and the other part area of the second wiring is located in the second through hole; and
the light-emitting subunit includes a first electrode and a second electrode, a part area of the first wiring is regarded as the first electrode, the second electrode is located on the side of the epitaxial layer away from the substrate, and the second electrode is connected to the second wiring.

In some embodiments of the present application, the epitaxial layer includes a first sublayer, a second sublayer and a third sublayer that are arranged on the substrate in sequence;
a part area of the first wiring is located in the first through hole, the other part area of the first wiring is located on a side of the first sublayer away from the substrate, a part area of the second wiring is located on a side of the third sublayer away from the substrate, and the other part area of the second wiring is located in the second through hole; and
the light-emitting subunit includes a first electrode and a second electrode, the first electrode is located on a side of the first sublayer away from the substrate, and insulated with the second sublayer and the third sublayer, the second electrode is located on a side of the third sublayer away from the substrate, the first electrode is electrically connected to the first wiring. and the second electrode is electrically connected to the second wiring.

In some embodiments of the present application, the epitaxial layer includes a first sublayer, a second sublayer and a third sublayer that are arranged on the substrate in sequence;
the first wiring is located in the first through hole, a part area of the second wiring is located between the third sublayer and the substrate, and insulated with the first sublayer and the second sublayer, and the other part area of the second wiring is located in the second through hole; and
the light-emitting subunit includes a first electrode and a second electrode, a part area of the first wiring is regarded as the first electrode, the second electrode is located between the substrate and the third sublayer, and insulated with the first sublayer and the second sublayer, and the second electrode is electrically connected to the second wiring.

In some embodiments of the present application, the light-emitting unit includes a plurality of light-emitting subunits, and the substrate is provided with a first through hole and a second through hole; and
the plurality of light-emitting subunits in a same light-emitting unit are arranged in series; the first wiring of one light-emitting subunit in the same light-emitting unit is located in the first through hole, a part area of the second wiring of another light-emitting subunit in the same light-emitting unit is located in the second through hole.

In some embodiments of the present application, a material of the substrate includes silicon.

In the second aspect, the embodiment of the present application provides a display device, the display device includes a cover plate and the array baseplate as described above, and the cover plate is located on a side of the substrate of the array baseplate away from the drive unit.

In the third aspect, the embodiment of the present application provides a preparation method of an array baseplate, including:
providing a substrate;
forming a semiconductor film on a side of the substrate;
forming a drive unit on a side of the substrate away from the semiconductor film; and
patterning the semiconductor film to obtain an epitaxial layer.

In some embodiments of the present application, after forming a semiconductor film on a side of the substrate, and before forming a drive unit on a side of the substrate away from the semiconductor film, the method further includes:
forming a protective layer on the semiconductor film.

In some embodiments of the present application, after forming a drive unit on a side of the substrate away from the semiconductor film, and before patterning the semiconductor film to obtain an epitaxial layer, the method further includes:
removing the protective layer.

In some embodiments of the present application, after forming a protective layer on the semiconductor film, and before forming a drive unit on a side of the substrate away from the semiconductor film, the method further includes:
forming a first through hole and a second through hole in the substrate;
filling conductive parts in the first through hole and the second through hole; wherein, the conductive part in the first through hole and the conductive part in the second through hole are electrically connected to the drive unit, respectively.

In some embodiments of the present application, an area delineated by an orthographic projection of an outer contour of the first through hole on the substrate is located within an orthographic projection of the epitaxial layer on the substrate, the conductive part in the first through hole is regarded as a first wiring electrically connected to the epitaxial layer, and the first wiring is in direct contact with a part area of the epitaxial layer.

In some embodiments of the present application, after patterning the semiconductor film to obtain an epitaxial layer, the method further includes:
forming an insulation layer; wherein the insulation layer covers a part area of a surface of the epitaxial layer away from the substrate, covers side surfaces of the epitaxial layer, and covers a part area of the substrate, and the insulation layer exposes a part area of the surface of the epitaxial layer away from the substrate, and exposes the conductive part in the second through hole.

In some embodiments of the present application, after forming an insulation layer, the method further includes:
forming a conductive layer, wherein the conductive layer is in direct contact with a part area of the surface of the epitaxial layer away from the substrate, a part area of the conductive layer is in direct contact with the conductive part in the second through hole, and the conductive layer and the conductive part in the second through hole are regarded as a second wiring electrically connected to the epitaxial layer.

The above description is merely a summary of the technical solutions of the present application. In order to more clearly know the technological means of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the

present application or the related art, the drawings that are required to describe the embodiments or the related art will be briefly described below. Apparently, the drawings that are described below are merely embodiments of the present application, and a person skilled in the art may obtain other drawings according to these drawings without paying creative work.

FIG. 1 to FIG. 5 are schematic structural diagrams of five array baseplates according to the embodiments of the present application;

FIG. 6 is a flow chart of a preparation method of an array baseplate according to an embodiment of the present application;

FIG. 7 to FIG. 12 are schematic diagrams of intermediate structures of a preparation method of an array baseplate according to the embodiments of the present application;

FIG. 13 is a schematic structural diagram of a display device according to an embodiment of the present application; and

FIG. 14 is a schematic structural diagram of a driving circuit according to an embodiment of the present application.

### DETAILED DESCRIPTION

The following will give a clear and complete description of the technical solution in the embodiments of the present application in combination with the drawings in the embodiments of the present application. Obviously, the described embodiments are only part of the embodiments of the present application, not all of them. Based on the embodiments in the present application, all other embodiments obtained by ordinary technicians in the art without creative work fall within the protection scope of the present application.

In the drawings, the thicknesses of the areas and the layers may be exaggerated for clarity. The same reference numerals in the drawings represent the same or similar structures, so their detailed description will be omitted. In addition, the attached drawings are only schematic illustrations of the present application, and are not necessarily drawn to scale.

In the embodiment of the present application, the words “first”, “second”, “third” and other words are used to distinguish the same or similar items with basically the same function and function, only for the purpose of clearly describing the technical solution of the embodiment of the present application, and cannot be understood as indicating or implying the relative importance or implying the quantity of the indicated technical features.

In the description of the present application, unless otherwise stated, “a/the plurality of” means two or more. The terms “up”, “down”, “left”, “right”, “inside” and “outside” indicate the orientation or position relationship based on the orientation or position relationship shown in the attached drawings, which is only for the convenience of describing the present application and simplifying the description, but not to indicate or imply that the machine or element referred to must have a specific orientation, be constructed and operated in a specific orientation, so it cannot be understood as a limitation of the present application.

Unless the context otherwise requires, the term “including/comprising” is interpreted as “including, but not limited to” in the entire specification and claims. In the description of the specification, the terms “one embodiment”, “some embodiments”, “exemplary embodiments”, “examples”, “specific examples” or “some examples” are intended to indicate that specific features, structures, materials or characteristics related to the embodiment or example are included in at least one embodiment or example of the present application. The schematic representation of the above terms does not necessarily refer to the same embodiment or example. In addition, the specific features, structures, materials or features described may be included in any one or more embodiments or examples in any appropriate manner.

The silicon-based light emitting diode (LED) micro-display technology is compatible with current semiconductor technology and suitable for mass production. Compared with liquid crystal on silicon (LCOS) display technology and digital light processing (DLP) micro-display technology, it does not need backlight, has a relatively thin structure, simple optical system design and fast response speed. Compared with organic light emitting diode (OLED) micro-display technology, it has the advantages of high brightness, high temperature resistance and long life. Among them, the LCOS is a silicon-based liquid crystal display technology, and the DLP is a digital light processing display technology, refer to relevant technologies for details.

At present, the silicon-based light-emitting diode micro-display products are prepared mostly based on the driver backplane and light-emitting diode chips arrayed on the silicon-based substrate. They are bonded through a dielectric metal layer. In the process of bonding the driver backplane and the light-emitting diode chips, the requirement of the bonding accuracy is very high, especially for the display products with high PPI (Pixels Per Inch, pixel density), the current alignment equipment is difficult to achieve accurate alignment. In addition, after the completion of the bonding, it is also necessary to remove the silicon-based substrate of the light-emitting diode chips. Chemical reagents, such as hydrogen fluoride (HF), will be used in the process of removing the silicon-based substrate. These chemical reagents will cause corrosion and damage to the circuit in the drive backplane, thus reducing the yield of the display product and reducing the display effect.

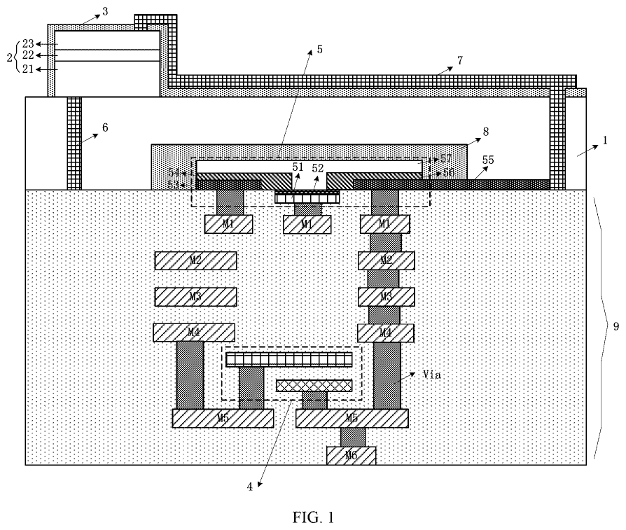

Based on this, the embodiment of the present application provides an array baseplate, referring to FIG. 1 to FIG. 5, including:
a substrate 1;
a drive unit 9 disposed on one side of the substrate 1; and
a light-emitting unit including at least one light-emitting subunit and disposed on a side of the substrate 1 away from the drive unit 9, wherein the light-emitting unit is electrically connected to the drive unit 9 through a wiring penetrating the substrate, and at least part area of each light-emitting subunit is in direct contact with the substrate 1.

In an exemplary embodiment, the above substrate 1 may be a silicon substrate.

In an exemplary embodiment, the substrate has a plurality of penetrating holes, and at least part area of part wirings passes through the holes of the substrate to connect the light-emitting unit on one side of the substrate and the drive unit on the other side of the substrate.

The specific structure and circuit design in the above drive unit 9) are not limited here, but can be determined according to the electrical requirements of the products.

For example, the drive unit may include a drive circuit. For example, the drive circuit may be the circuit including three transistors and one capacitor shown in FIG. 14, and may also be other types of drive circuits, which are not limited here.

For example, the drive unit may include a capacitor 4 and a transistor 5.

For example, the transistor 5 may be a thin film transistor (TFT) or a metal oxide semiconductor transistor (MOS).

As shown in FIG. 14 and FIG. 1, the substrate made of silicon and the drive unit may be called a drive backplane as a whole. The type of the drive backplane provided by the embodiment of the present application may be IP6M, 1P5M or IP8M. Among them, the drive backplane of IP6M type is taken as an example, which includes 1 layer of Poly-Si layer and 6 layers of metal layer. The Poly-Si layer is used to prepare the active layer of the transistor, and the 6 layers of metal layer are used to form a conductive pattern.

In addition, it needs to be noted that the substrate made of silicon and the light-emitting

unit can be called a light-emitting substrate as a whole. It can be understood that, in the array baseplate provided by the embodiment of the present application, the substrate of light-emitting unit and the substrate of the drive unit are shared, thus saving a layer of substrate, omitting the bonding process of the light-emitting unit and the drive backplane, and omitting the process of removing the substrate of the light-emitting unit after the bonding process.

In an exemplary embodiment, the light-emitting colors of the light-emitting subunits in the same light-emitting unit may be the same. Alternatively, the light-emitting colors of the light-emitting subunits in the same light-emitting unit may be different.

In an exemplary embodiment, insulating materials can be set between adjacent light-emitting subunits in the same light-emitting unit to avoid electrical signal interference between two adjacent light-emitting subunits.

For example, in the case that the light-emitting colors of the light-emitting subunits in the same light-emitting unit are the same, a light-transmitting material can be set between adjacent light-emitting subunits, and the type of the light-transmitting material can be determined according to the actual demand for refractive index to improve the luminous efficiency.

For example, in the case that the light-emitting colors of the light-emitting subunits in the same light-emitting unit are different, a shading layer can be set between adjacent light-emitting subunits to avoid the problem of color mixing between different colors of light.

For example, the light-emitting subunit may include an epitaxial layer 2. In some embodiments, the epitaxial layer 2 may include a first sublayer 21, a second sublayer 22 and a third sublayer 23. The first sublayer 21 may be a semiconductor sublayer, the third sublayer 23 may be a semiconductor sublayer, and the second sublayer 22 may be a quantum well sublayer (MQW). The semiconductor types of the first sublayer 21 and the third sublayer 23 are opposite. for example, the first sublayer 21 may be an N-type semiconductor sublayer, and the third sublayer 23 may be a P-type semiconductor sublayer. The N-type semiconductor sublayer may include N-type gallium nitride (N-GaN), and the P-type semiconductor sublayer may include P-type gallium nitride (P-GaN). It should be noted that the epitaxial layer here means an epitaxial layer in a broad sense, which not only includes the first sublayer 21, the second sublayer 22 and the third sublayer 23, but also includes other films used to improve the epitaxial growth performance and quality of semiconductor materials on the substrate, such as a transition sublayer.

In an exemplary embodiment, the above light-emitting subunits may be used to form a mini light emitting diode (Mini LED) or a micro light emitting diode (Micro LED). The size range of the Mini LED is 100 μm-300 μm, and the size range of the Micro LED is 0 μm-100 μm.

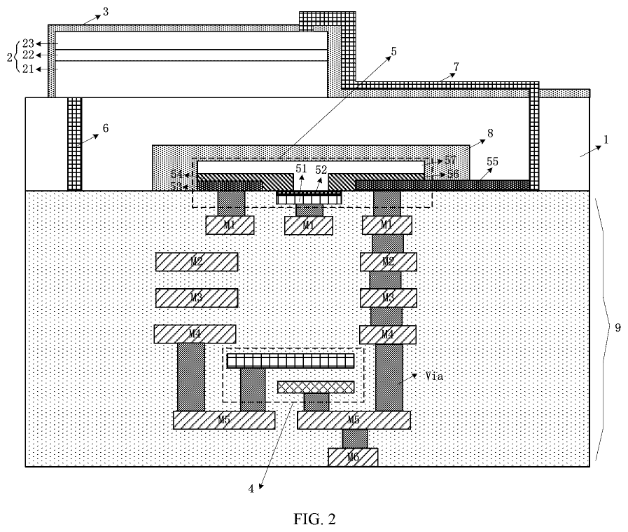

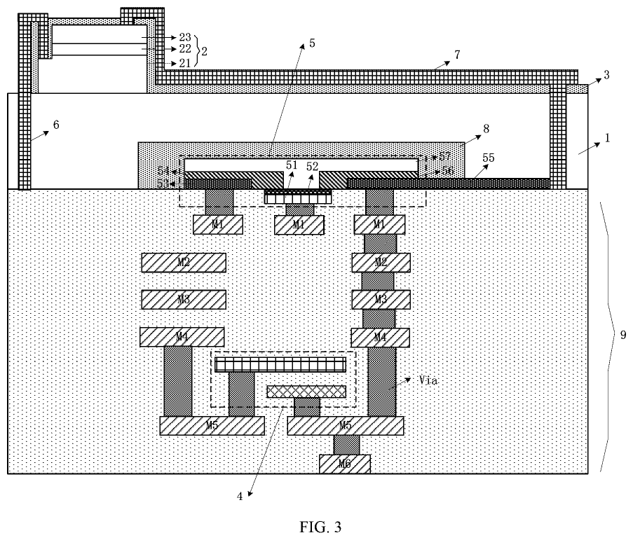

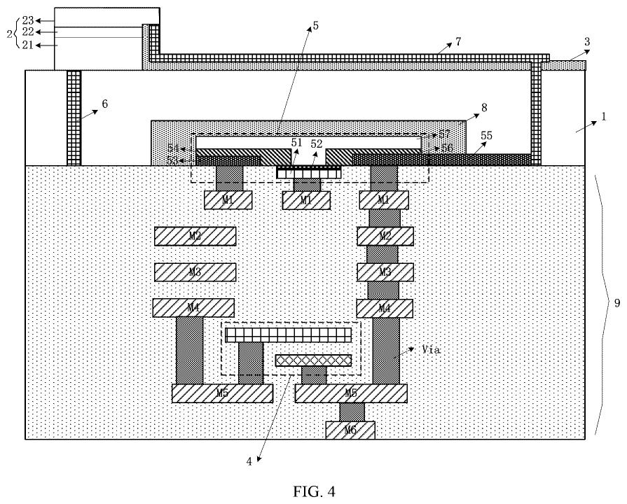

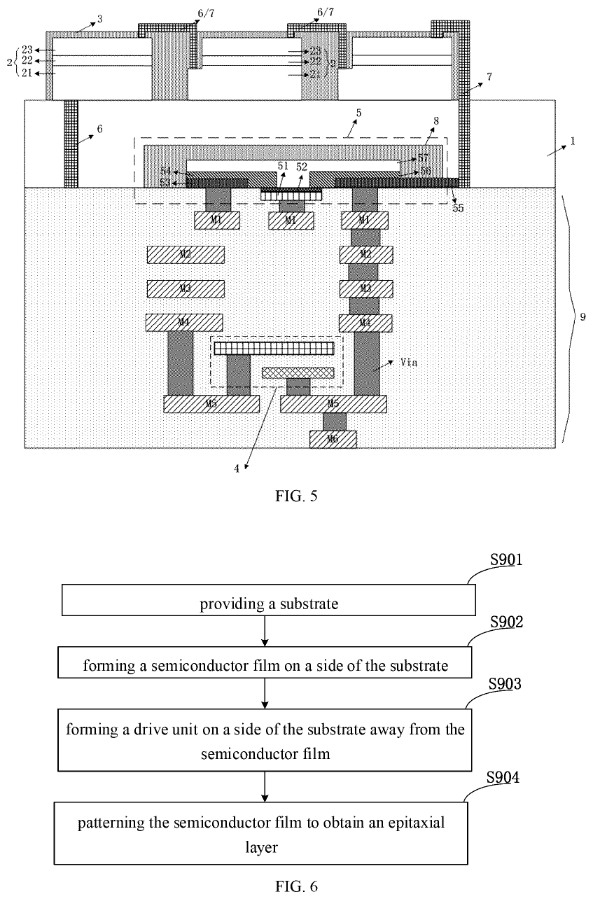

In an exemplary embodiment, at least part area of each light-emitting subunit directly contacts with the substrate 1, including but not limited to the following:
as shown in FIG. 1, FIG. 2 and FIG. 4, a part area of a surface of a side of each light-emitting subunit close to the substrate 1 are in direct contact with the substrate 1;
as shown in FIG. 3, the whole area of the surface of the side of each light-emitting subunit close to the substrate 1 are in direct contact with the substrate 1; and
as shown in FIG. 5, for the first light-emitting subunit on the left side, a part area of the surface of the side of each light-emitting subunit close to the substrate 1 is in direct contact with the substrate 1; for the other two light-emitting subunits. the whole area of the surface of the side of each light-emitting subunit close to the substrate 1 is in direct contact with the substrate 1.

The present application provides an array baseplate, the array baseplate includes: the substrate 1; the drive unit 9 disposed on one side of the substrate 1; and the light-emitting unit including at least one light-emitting subunit and disposed on a side of the substrate 1 away from the drive unit 9, wherein the light-emitting unit is electrically connected to the drive unit 9, and at least part area of each light-emitting subunit is in direct contact with the substrate 1. The light-emitting subunit of the array baseplate is located on one side of the substrate 1, the drive unit 9 is located on a side of the substrate away from the light-emitting subunit, and at least part area of the light-emitting subunit is in direct contact with the substrate 1. In the process of preparing the array baseplate, the light-emitting unit may be directly prepared on the substrate 1, thus shortening the preparation cycle, avoiding the problem of reducing the preparation efficiency caused by the massive transfer technology, avoiding the damage to the drive unit in the process after the bonding between the light-emitting unit and the drive unit, improving the yield of the array baseplate, and reducing the cost.

In some embodiments of the present application. referring to FIG. 1 and FIG. 5, the array baseplate includes a first wiring 6 and a second wiring 7, the light-emitting subunit includes an epitaxial layer 2; the first wiring 6 and the second wiring 7 are electrically connected to the epitaxial layer 2, and the first wiring 6 and the second wiring 7 are electrically connected to the drive unit 9; among them, at least part area of the epitaxial layer 2 is in direct contact with the substrate 1.

In an exemplary embodiment, the first wiring 6 is electrically connected to the common electrode (Vcom) in the drive unit 9, and the second wiring 7 is electrically connected to the transistor 5 in the drive unit 9. The common electrode is not drawn in the drawings provided in the embodiment of the present application. In practical application, the common electrode can be arranged on one layer of the multi-layer metal layers of the drive unit.

It should be noted that in the drawings provided by the embodiment of the present application, the light-emitting subunit only including the epitaxial layer 2 is taken as an example to illustrate. In practical applications, the light-emitting subunit may also include other structures and components. For details, please refer to related art, which will not be repeated here.

In practical applications, the vapor phase epitaxy method may be used to directly deposit and grow the semiconductor film on one side of the substrate 1, and then the epitaxial layer 2 is obtained after patterning.

In the embodiment of the present application, the epitaxial layer 2 is arranged on one side of the substrate 1, the drive unit 9 is located on a side of the substrate 1 away from the epitaxial layer 2, and at least part area of the epitaxial layer 2 is in direct contact with the substrate 1. During the preparation of the array baseplate, the epitaxial layer 2 may be directly deposited on one side of the substrate 1, and the drive unit 9 may be prepared on the side of the substrate 1 away from the epitaxial layer 2, thus shortening the preparation cycle, avoiding the problem of reducing the preparation efficiency caused by the massive transfer technology. avoiding the damage to the drive unit in the process after the bonding between the light-emitting unit and the drive unit, improving the yield of the array baseplate, and reducing the cost.

In some embodiments of the present application, the epitaxial layer 2 includes a transition sublayer, a first sublayer 21, a second sublayer 22 and a third sublayer 23 that are arranged on the substrate in sequence; at least part area of the transition sublayer is in direct contact with the substrate 1.

In an exemplary embodiment, a material of the transition sublayer may be a semiconductor material. Before depositing the first sublayer 21, a layer of transition sublayer is deposited to improve the adhesion of the first sublayer 21 on the substrate 1 and improve the reliability of the epitaxial layer 2. Among them, the material of the transition sublayer needs to match the material of the first sublayer 21 to a certain extent. The specific material of the transition sublayer can be determined according to the material of the first sublayer.

For example, the transition sublayer may be a single-layer structure film layer, or the transition sublayer may be a multi-layer structure film layer.

In the case of arranging the transition sublayer between the first sublayer and the substrate, the transition sublayer is in direct contact with the substrate.

In some embodiments of the present application, referring to FIG. 1 to FIG. 5, at least part area of at least one wiring of the first wiring 6 and the second wiring 7 passes through the substrate 1 and extends to the side of the substrate 1 disposing the drive unit 9, and is electrically connected to the drive unit 9.

For example, the first wiring 6 may be electrically connected to a cathode of the light-emitting subunit, and the second wiring 7 may be electrically connected to an anode of the light-emitting subunit.

For example, as shown in FIG. 1, FIG. 2 and FIG. 4, the first wiring 6 passes through the substrate 1, extends to the side of the substrate 1 disposing the drive unit 9 and directly contacts the drive unit 9. A part area of the second wiring 7 passes through the substrate 1, extends to the side of the substrate 1 disposing the drive unit 9 and is electrically connected to the drive unit 9.

For example, as shown in FIG. 3, a part area of the first wiring 6 passes through the substrate 1, extends to the side of the substrate 1 disposing the drive unit 9 and is electrically connected to the drive unit 9. A part area of the second wiring 7 passes through the substrate 1, extends to the side of the substrate 1 disposing the drive unit 9 and is electrically connected to the drive unit 9.

For example, as shown in FIG. 5, the first wiring 6 on the left side passes through the substrate 1, extends to the side of the substrate 1 disposing the drive unit 9 and is electrically connected to the drive unit 9, and a part area of the second wiring 7 on the right side passes through the substrate 1, extends to the side of the substrate 1 disposing the drive unit 9 and is electrically connected to the drive unit 9. Among them, the wiring with the mark 6/7 in the middle area refers to: because the three adjacent light-emitting subunits are arranged in series. the wiring may be used as the first wiring 6 of the previous light-emitting subunit and the second wiring 7 of the next light-emitting subunit.

It should be noted that in the embodiment of the present application, at least part area of each wiring used to electrically connect the drive unit and the light-emitting unit is located in the through hole arranged on the substrate, and the wiring passes through the through hole on the substrate to electrically connect the drive unit on one side of the substrate and the light-emitting unit on the other side of the substrate.

In an exemplary embodiment, for the array baseplate shown in FIG. 1 to FIG. 4, the electrodes in the same light-emitting unit that are electrically connected to each light-emitting subunit, such as the cathode, can be shared.

For example, the cathodes in the same light-emitting unit that are electrically connected to the light-emitting subunits can be electrically connected together by a conductive structure before being electrically connected to the driving electrode 9.

In an exemplary embodiment, the light-emitting subunit also includes a first electrode and a second electrode. The first electrode may be the cathode, and the second electrode may be the anode. In the drawings provided by the embodiment of the present application, the positions of the first electrode and the second electrode are not drawn.

In some embodiments of the present application, referring to FIG. 1 to FIG. 4, the light-emitting unit includes one light-emitting subunit, the substrate 1 is provided with a first through hole and a second through hole, at least part area of the first wiring 6 is located in the first through hole, and at least part area of the second wiring 7 is located in the second through hole.

In some embodiments of the present application, referring to FIG. 1 and FIG. 2, the first wiring 6 is located in the first through hole, a part area of the second wiring 7 is located on a side of the epitaxial layer 2 away from the substrate 1, and the other part area of the second wiring 7 is located in the second through hole; and
the light-emitting subunit includes a first electrode and a second electrode, a part area of the first wiring 6 is regarded as the first electrode, the second electrode is located on the side of the epitaxial layer 2 away from the substrate 1, and the second electrode is connected to the second wiring 7. At this time, the light-emitting subunit can be called a light-emitting subunit of a vertical structure.

In the exemplary embodiment, an area of an orthographic projection of a part of the first wiring 6 as the first electrode on the substrate 1 is greater than an area of an orthographic projection of the other part of the first wiring 6 on the substrate 1. In this way, there is sufficient contact area between the part of the first wiring 6 as the first electrode and the epitaxial layer 2 to improve the conductive effect.

In some embodiments of the present application, referring to FIG. 3, the epitaxial layer 2 includes a first sublayer 21, a second sublayer 22 and a third sublayer 23 that are arranged on the substrate 1 in sequence; a part area of the first wiring 6 is located in the first through hole, the other part area of the first wiring 6 is located on a side of the first sublayer 21 away from the substrate 1, a part area of the second wiring 7 is located on a side of the third sublayer 23 away from the substrate 1, and the other part area of the second wiring 7 is located in the second through hole. The light-emitting subunit includes a first electrode and a second electrode, the first electrode is located on a side of the first sublayer 21 away from the substrate 1, and insulated with the second sublayer 22 and the third sublayer 23, the second electrode is located on a side of the third sublayer 23 away from the substrate 1, the first electrode is electrically connected to the first wiring 6, and the second electrode is electrically connected to the second wiring 7. At this time, the light-emitting subunit may be called the light-emitting subunit of a formal structure.

It should be noted that in the embodiment of the present application, similar descriptions such as “one part, the other part” do not limit a certain structure to have only two parts. In practical applications, they can also include the third part and the fourth part. Similar descriptions such as “one, the other” do not limit a certain structure to have only two. They can also include the third and the fourth, which are only explained here.

In some embodiments of the present application, referring to FIG. 4, the epitaxial layer 2 includes a first sublayer 21, a second sublayer 22 and a third sublayer 23 that are arranged on the substrate 1 in sequence; the first wiring 6 is located in the first through hole, a part area of the second wiring 7 is located between the third sublayer 23 and the substrate 1, and insulated with the first sublayer 21 and the second sublayer 22, and the other part area of the second wiring 7 is located in the second through hole.

The light-emitting subunit includes a first electrode and a second electrode, a part area of the first wiring 6 is regarded as the first electrode, the second electrode is located between the substrate 1 and the third sublayer 23, and insulated with the first sublayer 21 and the second sublayer 22, and the second electrode is electrically connected to the second wiring 7. At this time, the light-emitting subunit may be called the light-emitting subunit of an inverted structure.

In an exemplary embodiment, the area of the orthographic projection of the part of the first wiring 6 as the first electrode on the substrate 1 is greater than the area of the orthographic projection of the other part of the first wiring 6 on the substrate 1. In this way, there is sufficient contact area between the part of the first wiring 6 as the first electrode and the epitaxial layer 2 to improve the conductive effect.

It should be noted that in practical applications, the array baseplate also includes the insulation layer 3. For the three different types of the light-emitting subunits, i.e., the vertical structure, the formal structure and the inverted structure, the arrangement positions of the insulation layer 3 are different. The attached drawings provided in the embodiment of the present application provide examples of the arrangement positions of the insulation layer 3, but do not serve as a limitation of the insulation layer 3, the details can be determined according to the actual needs and with reference to related art.

In some embodiments of the present application, referring to FIG. 5, the substrate 1 is provided with the first through hole and the second through hole, the light-emitting unit includes a plurality of light-emitting subunits, the plurality of light-emitting subunits in a same light-emitting unit are arranged in series; the first wiring 6 of one light-emitting subunit in the same light-emitting unit is located in the first through hole, a part area of the second wiring 7 of another light-emitting subunit in the same light-emitting unit is located in the second through hole.

The arrangement positions of the electrodes of the light-emitting subunits in FIG. 5 can refer to the positions of the electrodes of the structures as described above. There is no limit here. The details can be determined according to the actual needs. In an exemplary embodiment, when the light-emitting subunits in the same light-emitting unit are arranged in series, two adjacent light-emitting subunits in the same light-emitting unit are provided with an insulation layer 3 (for example, an area between two adjacent epitaxial layers 2 in FIG. 5 is provided with the insulation layer), and at least one electrode is arranged on the side of the insulation layer 3 away from the substrate 1.

In some embodiments of the present application, a material of the substrate 1 includes silicon.

In the embodiments of the present application, as shown in FIG. 14 and FIG. 1, the substrate made of silicon and the drive unit can be called the drive backplane as a whole. The type of the drive backplane provided by the embodiment of the present application may be IP6M. 1P5M or 1P8M. Take the IP6M type drive backplane as an example, which includes 1 layer of Poly-Si layer and 6 layers of metal layer. The Poly-Si layer is used to prepare the active layer of the transistor, and the 6 layers of metal layer are used to form the conductive pattern. In the drawings provided by the embodiment of the present application. The 6 layers of metal are marked as M1, M2, M3, M4, M5 and M6 in sequence according to the preparation sequence. The insulation layer is arranged between the metal layers, and the electrical connection between the metal layers can be realized by the conductive material filled in the via hole Via.

In addition, for example, the first control signal line G1 and the second control signal line G2 shown in FIG. 14 can be prepared on the first metal layer M1, the first power signal line VDD can be prepared on the second metal layer M2, the data line Data can be prepared on the third metal layer M3, and the second power signal line VSS can be prepared on the fifth metal layer M5.

For example, the transistor can include MOS tubes, which can include double-diffused metal oxide semiconductor (DMOS) tubes and complementary metal oxide semiconductor (CMOS) tubes.

For example, the array baseplate includes a deep N-well 8 (DNW) as shown in FIG. 1. The MOS tube 5 is located in the space isolated by the deep N-well 8. The MOS tube 5 specifically includes a gate 51, an active layer 52, a source 53, a light doped source 54, a drain 55, a light doped drain 56 and a medium voltage well (MV well). The specific structure and working principle of the MOS tube 5 can refer to the related art, which will not be repeated here.

For example, the capacitor 4 includes the first pole and the second pole. The specific materials of the first pole and the second pole of the capacitor are not limited here. For example, the materials can be metal or semiconductor materials.

In addition, it should be noted that the substrate 1 made of silicon and the light-emitting unit can be called the light-emitting substrate as a whole. It can be understood that in the array baseplate provided by the embodiment of the present application, the substrate of the light-emitting unit and the substrate of the drive unit are shared, thus saving a layer of substrate omitting the bonding process of the light-emitting unit and the drive backplane, and omitting the process of removing the substrate of the light-emitting unit after the bonding process.

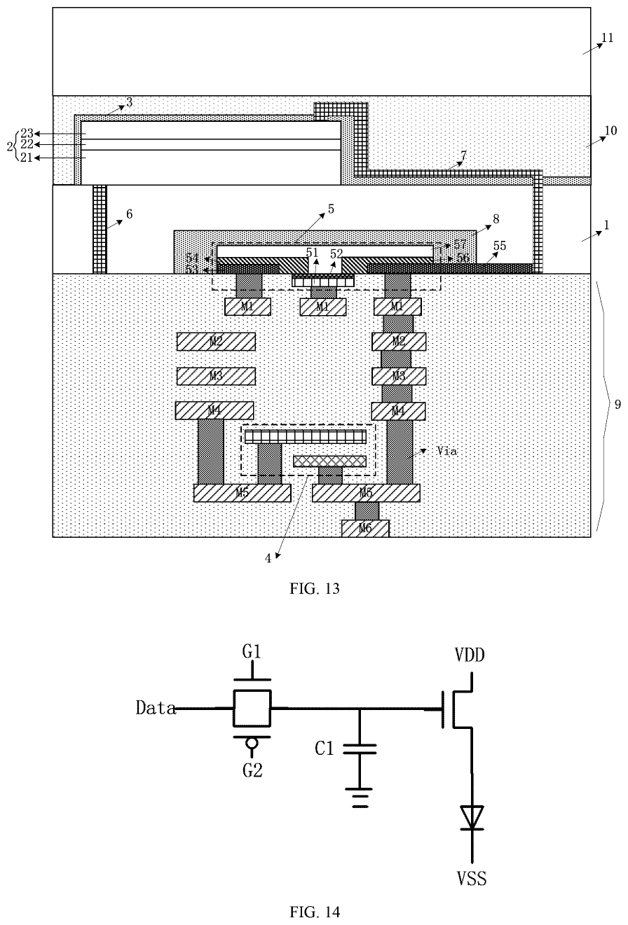

The embodiment of the present application provides a display device, referring to FIG. 13, the display device includes a cover plate 11 and the array baseplate as described above, and the cover plate 11 is located on a side of the substrate 1 of the array baseplate away from the drive unit 9.

In an exemplary embodiment, the material of the cover plate 11 can be glass, or the material of the cover plate 11 can be light-transmitting resin.

In an exemplary embodiment, a bonding layer 10 is also arranged between the cover plate 11 and the array baseplate. For example, the material of the bonding layer 10 can be a light-curing adhesive.

In an exemplary embodiment, the light-emitting device may be used as a backlight device, or as a display device.

In an exemplary embodiment, the light-emitting device may be a Mini-LED light-emitting device; alternatively, the light-emitting device may also be a Micro-LED light emitting device.

The display device provided by the embodiment of the present application includes the array baseplate described above. The light-emitting subunit in the array baseplate is located on one side of the substrate 1, the drive unit 9 is located on the side of the substrate 1 away from the light-emitting subunit, and at least part area of the light-emitting subunit is in direct contact with the substrate 1. In the process of preparing the array baseplate, the light-emitting unit can be directly prepared on the substrate 1, which shortens the preparation cycle, avoids the problem of reducing the preparation efficiency caused by the massive transfer technology, and also avoids the damage to the drive unit in the process after the bonding between the light-emitting unit and the drive unit, improves the yield of the display device, and reduces the production cost.

The embodiment of the present application provides a preparation method of an array baseplate, referring to FIG. 6, the method includes:

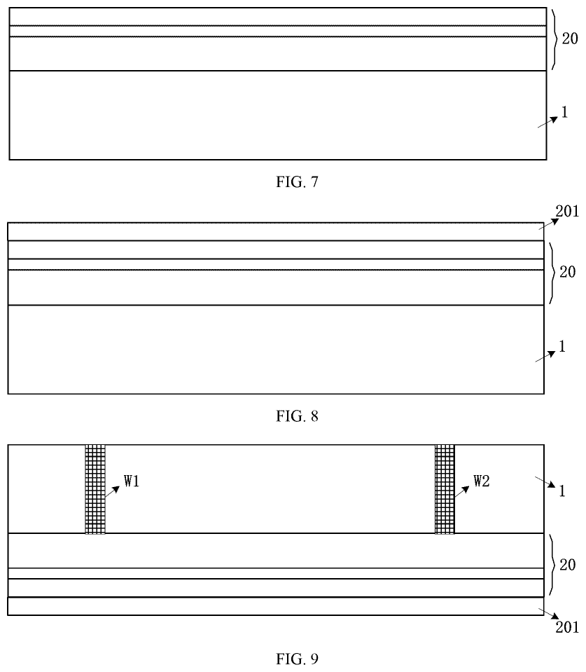

S901, providing a substrate 1 as shown in FIG. 7; wherein the substrate 1 may be a silicon substrate.

S902, forming a semiconductor film 20 on a side of the substrate 1.

For example, the semiconductor film 20 may include the first sub-film, the second sub-film and the third sub-film. The material of the first sub-film may include N-type semiconductor material, the material of the third sub-film can include P-type semiconductor material, and the material of the second sub-film can include quantum wells.

In practical application, the semiconductor film 20 is deposited on the substrate 1 by an epitaxial growth method.

S903, as shown in FIG. 9, forming a drive unit 9 on a side of the substrate 1 away from the semiconductor film 20.

The specific structure and circuit design in the above drive unit 9 are not limited here, but may be determined according to the electrical requirements of the product.

For example, the drive unit may include a drive circuit. For example, the drive circuit may be the drive circuit shown in FIG. 14 includes three transistors and a capacitor. Certainly, it may also be a drive circuit of other types or other structures, which is not limited here.

For example, the drive unit may include a capacitor 4 and a transistor 5.

For example, the transistor 5 may be a thin film transistor (TFT) or a metal oxide semiconductor transistor (MOS).

S904, patterning the semiconductor film 20 to obtain an epitaxial layer 2 as shown in FIG. 11.

The epitaxial layer 2 may include a first sublayer 21, a second sublayer 22 and a third sublayer 23. The first sublayer 21 may be a semiconductor sublayer, the third sublayer 23 may be a semiconductor sublayer, and the second sublayer 22 may be a quantum well sublayer (MQW). Among them, the first sublayer 21 and the third sublayer 23 have opposite semiconductor types. For example, the first sublayer 21 may be an N-type semiconductor sublayer, and the third sublayer 23 may be a P-type semiconductor sublayer. Among them, the N-type semiconductor sublayer may include N-type gallium nitride (N-GaN), and the P-type semiconductor sublayer may include P-type gallium nitride (P-GaN).

In addition, the epitaxial layer 2 may also include a transition sublayer between the substrate 1 and the first sublayer 21 to improve the adhesion between the substrate 1 and the first sublayer 21.

The preparation method of the array baseplate provided by the embodiment of the present application, in the process of preparing the array baseplate, may directly deposit the epitaxial layer 2 on the substrate 1, so that the substrate of the light-emitting unit and the substrate of the drive unit are shared, thus saving a layer of substrate, omitting the bonding process of the epitaxial layer of the light-emitting unit and the drive backplane, and omitting the process of removing the substrate of the light-emitting unit after the bonding process, which avoids the problem of reducing the preparation efficiency caused by the massive transfer technology, avoids the damage to the drive unit in the process after the bonding between the light-emitting unit and the drive unit, shortens the preparation cycle, improves the yield of the array baseplate, and reduces the cost.

In some embodiments of the present application, after step S902, forming a semiconductor film 20 on a side of the substrate 1, and before step S903, forming a drive unit 9 on a side of the substrate 1 away from the semiconductor film 20, the method further includes:

S9021, forming a protective layer 201 shown in FIG. 8 on the semiconductor film.

In an exemplary embodiment, a material of the protective layer 201 may be photoresist.

In some embodiments of the present application, after step S903, forming a drive unit 9 on a side of the substrate 1 away from the semiconductor film 20, and before step S904, patterning the semiconductor film 20 to obtain an epitaxial layer 2, the method further includes:

step S9031, removing the protective layer 201.

In the embodiment of the present application. after forming the semiconductor film 20. the protective layer 201 shown in FIG. 8 is formed first on the semiconductor film 20, and then the drive unit 9 is prepared on the other side of the substrate 1 to prevent damage to the semiconductor film 20 during the preparation of the drive unit 9. After forming the drive unit 9 on the side of the substrate 1 away from the semiconductor film 20. the protective layer 201 is removed, to further perform patterning processing on the semiconductor film 20.

It should be noted that the process of forming the semiconductor film 20 requires high temperature conditions, and the high temperature conditions will damage the drive unit 9, so the semiconductor film 20 is formed first, and then the drive unit 9 is formed. In addition, in practical applications, if after forming the semiconductor film 20, it is directly patterned to obtain the epitaxial layer 2, and then the drive unit 9 is formed, then in the process of forming the drive unit 9, precise alignment requirements are required to facilitate the electrical connection of the subsequent drive unit and the epitaxial layer at a good temperature. This requires very high alignment accuracy of the equipment, and because the silicon substrate itself is opaque. it is difficult to achieve in the actual preparation process. In the implementation example of the present application, the protective layer 201 is formed after forming the semiconductor film 20 to protect the semiconductor film 20, and then the drive unit 9 is formed, finally, the protective layer 201 is removed, and then the semiconductor film 20 is patterned. Thus omitting the bonding process between the epitaxial layer 2 in the light-emitting unit and the drive backplane. and omitting the process of removing the substrate of the light-emitting unit after the bonding process, so as to avoid the reduction of the preparation efficiency caused by the massive transfer technology, which also avoids the damage to the drive unit in the process after the bonding technology between the light-emitting unit and the drive unit, reduces the difficulty of the preparation process. shortens the preparation cycle, improves the yield of the array baseplate. and reduces the cost.

In some embodiments of the present application, after step S9021, forming a protective layer 201 on the semiconductor film 20, and before step S903, forming a drive unit 9 on a side of the substrate 1 away from the semiconductor film 20, the method further includes:

step S9022, forming a first through hole W1 and a second through hole W2 shown in FIG. 9 in the substrate 1;

step S9023, filling conductive parts in the first through hole W1 and the second through hole W2; wherein, the conductive part in the first through hole W1 and the conductive part in the second through hole W2 are electrically connected to the drive unit 9, respectively.

In an exemplary embodiment, a material of the conductive part may be copper (Cu) or tungsten (W).

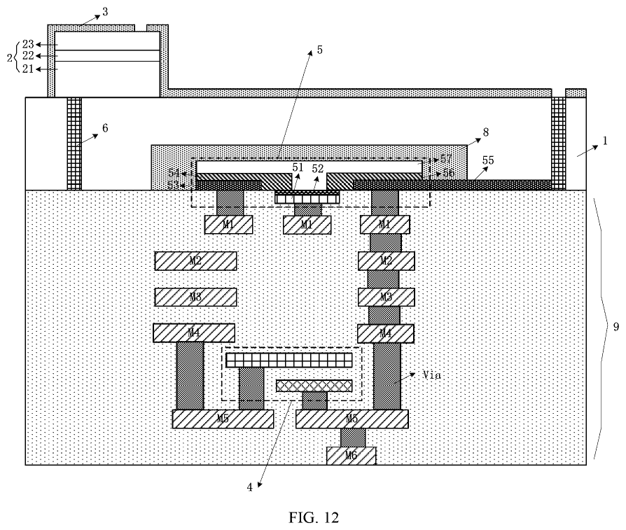

In some embodiments of the present application, referring to FIG. 12, an area delineated by an orthographic projection of an outer contour of the first through hole W1 on the substrate 1 is located within an orthographic projection of the epitaxial layer 2 on the substrate 1, the conductive part in the first through hole W1 is regarded as a first wiring 6 electrically connected to the epitaxial layer 2, and the first wiring 6 is in direct contact with a part area of the epitaxial layer 2.

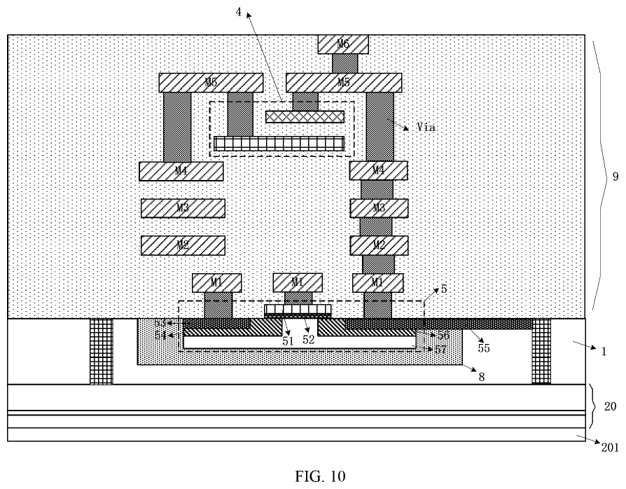

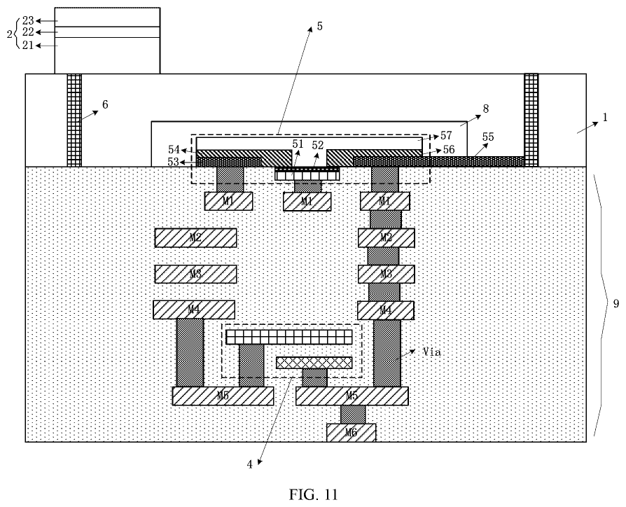

It should be noted that the drive unit is formed after filling the conductive parts in the first through hole W1 and the second through hole W2 in step S9023. In the process of forming the drive unit, accurate alignment of the conductive pattern is required to make the drive unit electrically connected to the conductive part in the first through hole W1 and the conductive part in the second through hole W2. For example, referring to FIG. 10, the drain 55 of the transistor 5 in the drive unit 9 is electrically connected to the conductive part in the second through hole W2.

In practical applications, since the first through hole W1 and the second through hole W2 pass through the substrate 1, the conductive parts filled in the first through hole W1 and the second through hole W2 can be directly observed from the side of the substrate 1 close to the drive unit 9, the precise alignment process at this time is easy to achieve and less difficult.

In some embodiments of the present application, after S904, patterning the semiconductor film 20 to obtain an epitaxial layer 2, the method further includes:

S9041, forming an insulation layer 3.

In an exemplary embodiment, referring to FIG. 12, the insulation layer 3 covers a part area of a surface of the epitaxial layer 2 away from the substrate 1, covers side surfaces of the epitaxial layer 2. and covers a part area of the substrate 1, and the insulation layer 3 exposes a part area of the surface of the epitaxial layer 2 away from the substrate 1, and exposes the conductive part in the second through hole W2.

In some embodiments of the present application, after step S9041, forming an insulation layer 3, the method further includes:

S9042, forming a conductive layer, wherein the conductive layer is in direct contact with a part area of the surface of the epitaxial layer 2 away from the substrate 1, a part area of the conductive layer is in direct contact with the conductive part in the second through hole W2, and the conductive layer and the conductive part in the second through hole W2 are regarded as a second wiring 7 electrically connected to the epitaxial layer 2.

In an exemplary embodiment, the first wiring 6 is electrically connected to the common electrode (Vcom) in the drive unit 9, and the second wiring 7 is electrically connected to the drain of the transistor 5 in the drive unit 9. The common electrode is not drawn in the drawings provided in the embodiment of the present application. In practical application, the common electrode can be set on one of the multi-layer metal layers (M1-M5) of the drive unit.

For example, the first wiring 6 may be the cathode, and the second wiring 7 may be the anode.

The specific structure of the array baseplate prepared by the preparation method provided by the embodiment of the present application may also refer to the previous description of the structure of the array baseplate. In addition, here only introduces the preparation method of the structure related to the invention point of the array baseplate. The preparation method of other structures and components in the array baseplate provided by the embodiment of the present application can refer to the related art, which will not be repeated here.

The above is only the specific implementation of the present application, but the scope of protection of the present application is not limited to this. Any technical personnel familiar with the technical field can easily think of changes or replacements within the scope of technology disclosed in the present application, which should be covered in the scope of protection of the present application. Therefore, the scope of protection of the present application shall be subject to the scope of protection of the claims.

1. An array baseplate, comprising:
a substrate;
a drive unit disposed on one side of the substrate; and
a light-emitting unit comprising at least one light-emitting subunit and disposed on a side of the substrate away from the drive unit, wherein the light-emitting unit is electrically connected to the drive unit through a wiring penetrating the substrate, and at least part area of each light-emitting subunit is in direct contact with the substrate.

2. The array baseplate according to claim 1, wherein the array baseplate comprises a first wiring and a second wiring, the light-emitting subunit comprises an epitaxial layer; the first wiring and the second wiring are electrically connected to the epitaxial layer, and the first wiring and the second wiring are electrically connected to the drive unit;
wherein, at least part area of the epitaxial layer is in direct contact with the substrate.

3. The array baseplate according to claim 2, wherein the epitaxial layer comprises a transition sublayer, a first sublayer, a second sublayer and a third sublayer that are arranged on the substrate in sequence;
wherein, at least part area of the transition sublayer is in direct contact with the substrate.

4. The array baseplate according to claim 2, wherein at least part area of at least one wiring of the first wiring and the second wiring passes through the substrate and extends to the side of the substrate disposing the drive unit, and is electrically connected to the drive unit.

5. The array baseplate according to claim 4, wherein the light-emitting unit comprises one light-emitting subunit, the substrate is provided with a first through hole and a second through hole, at least part area of the first wiring is located in the first through hole, and at least part area of the second wiring is located in the second through hole.

6. The array baseplate according to claim 5, wherein the first wiring is located in the first through hole, a part area of the second wiring is located on a side of the epitaxial layer away from the substrate, and the other part area of the second wiring is located in the second through hole; and
the light-emitting subunit comprises a first electrode and a second electrode, a part area of the first wiring is regarded as the first electrode, the second electrode is located on the side of the epitaxial layer away from the substrate, and the second electrode is connected to the second wiring.

7. The array baseplate according to claim 5, wherein the epitaxial layer comprises a first sublayer, a second sublayer and a third sublayer that are arranged on the substrate in sequence;
a part area of the first wiring is located in the first through hole, the other part area of the first wiring is located on a side of the first sublayer away from the substrate, a part area of the second wiring is located on a side of the third sublayer away from the substrate, and the other part area of the second wiring is located in the second through hole; and
the light-emitting subunit comprises a first electrode and a second electrode, the first electrode is located on a side of the first sublayer away from the substrate, and insulated with the second sublayer and the third sublayer, the second electrode is located on a side of the third sublayer away from the substrate, the first electrode is electrically connected to the first wiring, and the second electrode is electrically connected to the second wiring.

8. The array baseplate according to claim 5, wherein the epitaxial layer comprises a first sublayer, a second sublayer and a third sublayer that are arranged on the substrate in sequence;
the first wiring is located in the first through hole, a part area of the second wiring is located between the third sublayer and the substrate, and insulated with the first sublayer and the second sublayer, and the other part area of the second wiring is located in the second through hole; and
the light-emitting subunit comprises a first electrode and a second electrode, a part area of the first wiring is regarded as the first electrode, the second electrode is located between the substrate and the third sublayer, and insulated with the first sublayer and the second sublayer, and the second electrode is electrically connected to the second wiring.

9. The array baseplate according to claim 4, wherein the light-emitting unit comprises a plurality of light-emitting subunits, and the substrate is provided with a first through hole and a second through hole; and
the plurality of light-emitting subunits in a same light-emitting unit are arranged in series; the first wiring of one light-emitting subunit in the same light-emitting unit is located in the first through hole, a part area of the second wiring of another light-emitting subunit in the same light-emitting unit is located in the second through hole.

10. The array baseplate according to claim 1, wherein a material of the substrate comprises silicon.

11. A display device, wherein the display device comprises a cover plate and the array baseplate according to claim 1, and the cover plate is located on a side of the substrate of the array baseplate away from the drive unit.

12. A preparation method of an array baseplate, comprising:
providing a substrate;
forming a semiconductor film on a side of the substrate;
forming a drive unit on a side of the substrate away from the semiconductor film; and
patterning the semiconductor film to obtain an epitaxial layer.

13. The preparation method according to claim 12, wherein
after forming a semiconductor film on a side of the substrate, and before forming a drive unit on a side of the substrate away from the semiconductor film, the method further comprises:
forming a protective layer on the semiconductor film.

14. The preparation method according to claim 13, wherein after forming a drive unit on a side of the substrate away from the semiconductor film, and before patterning the semiconductor film to obtain an epitaxial layer, the method further comprises:
removing the protective layer.

15. The preparation method according to claim 13, wherein after forming a protective layer on the semiconductor film, and before forming a drive unit on a side of the substrate away from the semiconductor film, the method further comprises:
forming a first through hole and a second through hole in the substrate;
filling conductive parts in the first through hole and the second through hole; wherein, the conductive part in the first through hole and the conductive part in the second through hole are electrically connected to the drive unit, respectively.

16. The preparation method according to claim 15, wherein an area delineated by an orthographic projection of an outer contour of the first through hole on the substrate is located within an orthographic projection of the epitaxial layer on the substrate, the conductive part in the first through hole is regarded as a first wiring electrically connected to the epitaxial layer, and the first wiring is in direct contact with a part area of the epitaxial layer.

17. The preparation method according to claim 15, wherein after patterning the semiconductor film to obtain an epitaxial layer, the method further comprises:
forming an insulation layer; wherein the insulation layer covers a part area of a surface of the epitaxial layer away from the substrate, covers side surfaces of the epitaxial layer, and covers a part area of the substrate, and the insulation layer exposes a part area of the surface of the epitaxial layer away from the substrate, and exposes the conductive part in the second through hole.

18. The preparation method according to claim 17, wherein after forming an insulation layer, the method further comprises:
forming a conductive layer, wherein the conductive layer is in direct contact with a part area of the surface of the epitaxial layer away from the substrate, a part area of the conductive layer is in direct contact with the conductive part in the second through hole, and the conductive layer and the conductive part in the second through hole are regarded as a second wiring electrically connected to the epitaxial layer.
